(19) United States
(12) Patent Application Publication
(10) Pub. No.: US 2025/0349350 A1
(43) Pub. Date: Nov. 13, 2025

(54) MEMORY DEVICES HAVING MIDDLE STRAP AREAS FOR ROUTING POWER SIGNALS

(71) Applicant: Taiwan Semiconductor Manufacturing Company, Ltd., Hsin-Chu (TW)

(72) Inventors: Ping-Wei Wang, Hsin-Chu (TW); Jui-Lin Chen, Taipei City (TW); Feng-Ming Chang, Hsinchu County (TW)

(21) Appl. No.: 19/277,194

(22) Filed: Jul. 22, 2025

Related U.S. Application Data
(63) Continuation of application No. 18/427,248, filed on Jan. 30, 2024.
(60) Provisional application No. 63/591,465, filed on Oct. 19, 2023.

(51) Int. Cl. G11C 11/412; G11C 11/417; H10B 10/00

(52) U.S. Cl. CPC G11C 11/412; G11C 11/417; H10B 10/12

(57) ABSTRACT

One aspect of the present disclosure pertains to a device. The device includes a memory macro having a frontside and a backside along a vertical direction. The memory macro includes edge strap areas extending lengthwise along a first direction at edges of the memory macro, a memory cell area having a plurality of memory cells, where the memory cell area is disposed between the edge strap areas along a second direction perpendicular to the first direction, and a middle strap area extending lengthwise along the first direction and disposed between the edge strap areas along the second direction, where the middle strap area divides the memory cell area into two memory cell domains. The middle strap area includes a feedthrough circuit that routes a power signal line of one of the plurality of memory cells to the backside of the memory macro.

### PRIORITY DATA

This is a continuation application of U.S. patent application Ser. No. 18/427,248, filed Jan. 30, 2024, which claims the benefit of U.S. Provisional Application No. 63/591,465 filed Oct. 19, 2023, each of which is herein incorporated by reference in its entirety.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, power signals may be routed to a backside of a semiconductor device for power and chip space optimization. For example, memory devices such as static random access memory (SRAM) devices may have their bit cell active regions connected to backside vias which then route to corresponding backside metal lines electrically connected to high voltage power supply Vdd or low voltage power supply Vss (or ground). However, for high density memory cells with smaller sized active regions, the backside vias may be blocked or not properly formed due to process limitations. This is because the backside vias are defined by the critical dimension of the active regions. In this case, power signals such as Vdd and Vss cannot be provided from the back side. Instead, the power signals are only provided from the front side to the back side from the edge strap areas of the memory macro. However, long routing from the edges of the memory macro create high resistance and degrades the Vmax of the supply voltage (e.g., writing voltage).

Therefore, although existing structures for providing power routing from edge strap areas (i.e., edges of a memory macro) have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a device having an SRAM circuit area (or memory macro) with a middle strap area between edge strap areas, according to an embodiment of the present disclosure.

FIG. 2 illustrates a circuit diagram of an SRAM array as part of the memory macro in FIG. 1, according to an embodiment of the present disclosure.

FIGS. 3-7 illustrate top view device layouts of an SRAM array as part of the SRAM circuit area in FIG. 1 and corresponding to the circuit diagram of FIG. 2, according to an embodiment of the present disclosure.

FIG. 8 illustrates a top view and a cross-sectional view of an SRAM circuit area with a middle strap area between edge strap areas, according to an embodiment of the present disclosure.

FIG. 9A-9C illustrates a top view of an SRAM circuit area with even number of domains between strap areas, according to an embodiment of the present disclosure.

FIG. 9D illustrates a graph showing improvements to voltage drop depending on the number of domains in an SRAM circuit area.

FIGS. 10A-10B illustrates a top view of an SRAM circuit area with odd number of domains between strap areas, according to an embodiment of the present disclosure.

FIG. 11A illustrates a top view of an IC structure (or device) having an SRAM circuit area with two edge strap areas, according to an embodiment of the present disclosure.

FIG. 11B illustrates a top view of an IC structure (or device) having an SRAM circuit area with one edge strap area, according to an embodiment of the present disclosure.

FIG. 12A illustrates a top view of an IC structure (or device) having an SRAM circuit area with multiple middle strap areas between edge strap areas, according to an embodiment of the present disclosure.

FIG. 12B illustrates a zoomed-in top view of a middle strap area between SRAM arrays of the SRAM circuit area of FIG. 12A, according to an embodiment of the present disclosure.

FIG. 12C illustrates a zoomed-in top view of an edge strap area between the SRAM circuit area and logic device circuit area of FIG. 12A, according to an embodiment of the present disclosure.

FIG. 13A illustrates a top view of a middle strap area in an SRAM circuit area, according to an embodiment of the present disclosure.

FIG. 13B illustrates a cross-sectional view of a feedthrough circuit area of the middle strap area in FIG. 13A, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to semiconductor devices, and particularly to memory devices such as static random access memory (SRAM) devices having middle strap areas between edge strap areas. The edge strap areas define the edge boundaries of a memory macro. The memory macro includes a plurality of memory cells such as an array of SRAM cells, each cell having a plurality of metal routing lines including power line connections that connect to power source or to ground. These power line connections are electrically connected to source/drain (S/D) features in the SRAM cells and provide routing to power pull-up and pull-down transistors of the memory macro. For backside power routing, power may be routed from a back side of the memory macro through the edge strap areas and also from one or more middle strap areas embedded in the memory macro. Note that the edge strap and middle strap areas do not contain any SRAM cells. Instead, they include vertical metal routings to route power signals from a front side of the memory device to a back side of the memory device. Advantages of incorporating the middle strap areas (in addition to existing edge strap areas) include high density current discharge and improving writing voltage (Vmax) due to shorter routing of power signals. Vmax improvement can be greater than 200 mV compared to without having the middle strap areas.

As explained in more detail with respect to the accompanying figures, the middle strap areas may divide a memory macro into multiple domains. In an embodiment, each domain may include 32, 62, 128, or 256 bit cells depending on the number of middle strap areas for a 512 bit memory macro. Each of the middle strap areas includes a feedthrough circuit that routes a power signal line from a front side of the memory macro to a back side of the memory macro. The power signal line includes frontside metal features that electrically connect source/drain features of a memory cell to a frontside metal line. The frontside metal line is then electrically connected to a backside metal line under the memory macro through a feedthrough circuit in the middle strap area. The backside metal line may then electrically connect to high voltage power supply Vdd or low voltage power supply Vss (or ground). In various embodiments, the memory macro may be divided into an even number of domains by an odd number of middle strap areas, or the memory macro may be divided into an odd number of domains by an even number of middle strap areas. In various embodiments, the memory macro may be sandwiched between logic circuit areas, where the edge strap areas separate memory cells in the memory macro from logic cells in the logic circuit areas. In various embodiments, there may only be one edge strap area on one side of the memory macro, and on the other side of the memory macro, memory cells in the memory macro directly abut logic cells in the logic circuit areas without an intervening edge strap area.

The present disclosure also contemplates having backside vias that directly connect source/drain features in the memory cells to a backside metal line. The backside metal line then routes to Vdd or Vss. However, for high density memory cells with smaller sized active regions (e.g., active regions with widths 10 nm or smaller), some of the backside vias may be blocked or not properly formed due to process limitations caused by overlay shift or under-penetration. In this case, power signals such as Vdd and Vss cannot be provided through the backside vias. Instead, the power signals are only provided from the front side to the back side from the edge strap areas of the memory macro. However, long routing from the edges of the memory macro create high resistance and degrades the Vmax of the supply voltage (e.g., writing voltage). By incorporating the middle strap areas in the memory macro, shorter routing is made possible to lower resistance and improve Vmax.

The present disclosure focuses on providing power routing to the back side of a memory device for improving process window and power performance. However, in addition to providing power line connections to the back side of a memory device, power line connections may also be provided from a front side of the memory device for dual side power routing. In some cases, dual side power routing can reduce power consumption by more than 30% for better power performance.

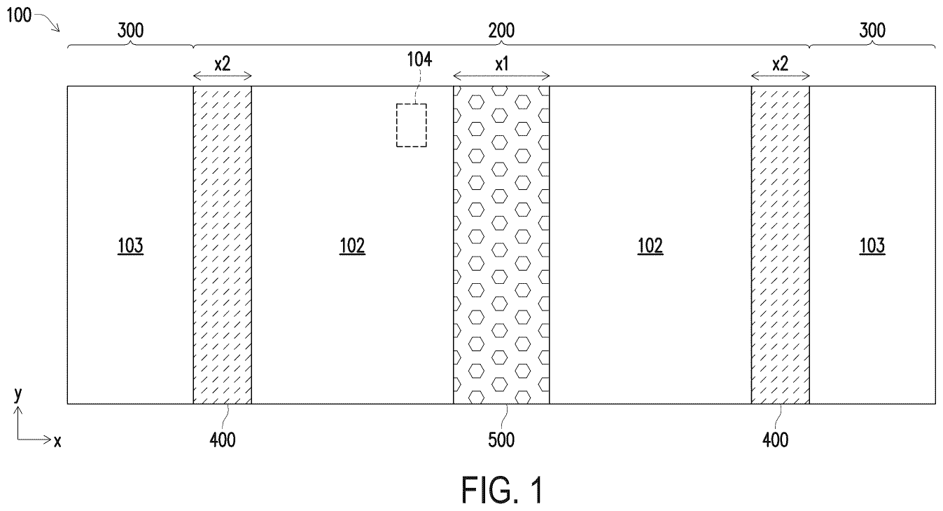

FIG. 1 illustrates a device 100 having an SRAM circuit area 200, which is also referred to as a memory macro 200. The device 100 can be a memory device integrated with logic components. Alternatively, the device 100 may be part of a microprocessor, an application specific integrated circuit (ASIC), a field programmable gate array (FPGA), or a digital signal processor (DSP). The exact functionality of the device 100 is not a limitation to the provided subject matter. The memory macro 200 may be a single-port SRAM macro, a dual-port SRAM macro, or other types of memory macro. The memory macro 200 includes memory cell areas 102 having arrays of memory cells 104 that store memory bits (e.g., 512 SRAM cells for storing 512 bits). In the present embodiment, a single memory bit is stored in a single memory cell 104. The memory cell areas 102 contain all the memory bits (implemented as transistors) of the memory macro 200. The device 100 may also include peripheral logic circuits 300 adjacent to the memory macro 200 (along the x direction) for implementing various functions such as write and/or read address decoder, word/bit selector, data drivers, memory self-testing, etc. The logic circuits 300 include logic cell areas 103, which may contain arrays of standard logic cells for implementing input/output (I/O) blocks. Each of the memory bits and the logic circuits may be implemented with various PMOS and NMOS transistors such as planar transistors, FinFET, gate-all-around (GAA) nanosheet transistors, GAA nanowire transistors, or other types of transistors. Further, the memory macro 200 and the logic circuits 300 may include various contact features (or contacts), vias, and metal lines for connecting the source, drain, and gate electrodes (or terminals) of the transistors to form an integrated circuit.

Still referring to FIG. 1, the memory macro 200 includes two edge strap areas 400. The edge strap areas 400 are located at the very edges of the memory macro in the x direction and extend lengthwise along the y direction. The memory macro 200 further includes one or more middle strap areas 500 disposed laterally between the edge strap areas 400 along the x direction. For purposes of simplicity, only one middle strap area 500 is shown. The edge strap areas 400 and the middle strap area 500 do not contain memory bits and are used for routing power signal lines from a frontside to a backside of the device 100. As such, edge strap areas 400 and the middle strap area 500 do not contain any transistors associated with implementing any memory cells 104.

Still referring to FIG. 1, the middle strap areas 500 may have a first width x1 along the x direction, the edge strap areas 400 may have a second width x2 along the x direction, and the first width x1 is greater than the second width x2. This is due to the middle strap areas 500 requiring larger (or more) buffer regions than the edge strap areas 400. Buffer regions refer to idle areas at the edges of the middle strap and edge strap areas 400 and 500 (not shown). The buffer regions provide metal routing and also isolation from active transistors in the memory cell and logic cell areas 102 and 103. The buffer regions disposed adjacent memory cell areas 102 may require a greater spacing than the buffer regions disposed adjacent logic cell areas 103. This is because memory cell routing and isolation may be more sensitive than logic cell routing and isolation. In some embodiments, for the edge strap areas 400, there are no buffer regions adjacent logic cell areas 103. As such, since one side of the edge strap areas 400 is adjacent to a logic cell area 103, and both sides of the middle strap areas 500 are adjacent to memory cell areas 102, the middle strap areas 500 may span wider in the x direction than the edge strap areas 400.

Still referring to FIG. 1, the edge strap areas 400 and the middle strap areas 500 do not include any well tap or well pick-up structures for supplying voltages (or biasing) to the N wells and P wells in the memory macro 200. No well taps are necessary because the device 100 is a backside power device having backside interconnect features. As such, when forming the device 100, a backside surface of the device 100 is grinded such that the N wells and P wells are discontinuous and adequately isolated from each other. As described herein, instead of having well tap structures, the edge strap and middle strap areas 400 and 500 include feedthrough circuit structures that electrically connect between front and back sides of the device 100.

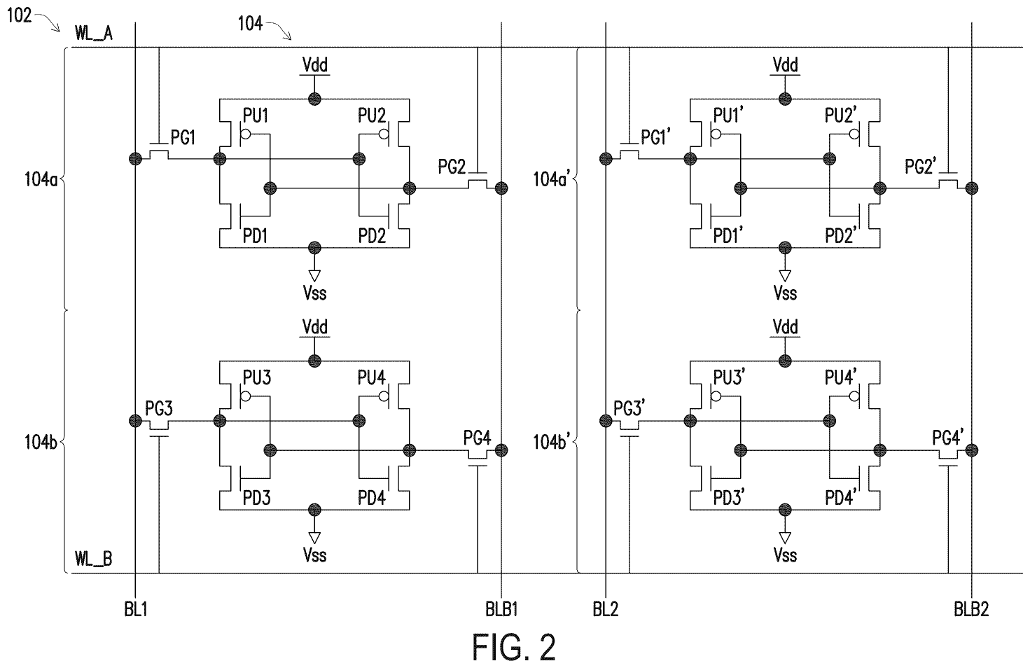

FIG. 2 illustrates a circuit diagram of an SRAM array as part of the memory macro 200 in FIG. 1. More specifically, the circuit diagram corresponds to an SRAM array of four memory cells 104 (or SRAM cells 104) in a memory cell area 102 of the memory macro 200. The SRAM array includes SRAM cells 104a, 104a′, 104b, and 104b′. Each of the SRAM cells 104a, 104a′, 104b, and 104b′ is formed of six transistors (two pull-down transistors, two pull-up transistors, and two pass-gate transistors). Each transistor is defined by a source, a drain, and a gate. Each SRAM cell 104 stores a bit of memory through the pull-down and pull-up transistors, and the SRAM cells are addressed by word lines and bit lines through the pass-gate transistors.

The SRAM cell 104a includes pull-up transistors PU1 and PU2, pull-down transistors PD1 and PD2, and pass gate transistors PG1 and PG2. The sources of PU1 and PU2 are coupled together and connected to high voltage Vdd. The sources of PD1 and PD2 are coupled together and connected to low source voltage Vss or ground. The gates of PU1 and PD1 are coupled together and connected to the common drains of PU2, PD2 and PG2. The gates of PU2 and PD2 are coupled together and connected to the common drains of PU1, PD1, and PG1. PU1, PU2, PD1, and PD2 form a first set of cross coupled inverters to store a data bit. The source of PG1 is connected to a first bit line BL1 and the source of PG2 is connected to a first bit line bar BLB1. The gates of PG1 and PG2 are connected to a first word line WL_A.

The SRAM cell 104b includes pull-up transistors PU3 and PU4, pull-down transistors PD3 and PD4, and pass gate transistors PG3 and PG4. The sources of PU3 and PU4 are coupled together and connected to high voltage Vdd. The sources of PD3 and PD4 are coupled together and connected to low voltage Vss or ground. The gates of PU3 and PD3 are coupled together and connected to the common drains of PU4, PD4 and PG4. The gates of PU4 and PD4 are coupled together and connected to the common drains of PU3, PD3, and PG3. PU3, PU4, PD3, and PD4 form a second set of cross coupled inverters to store a data bit. The source of PG3 is connected to the same first bit line BL1 and the source of PG4 is connected to the same first bit line bar BLB1. The gates of PG3 and PG4 are connected to a second word line WL_B.

The SRAM cells 104a′ and 104b′ are configured similarly to the respective SRAM cells 104a and 104b. The SRAM cells 104a′ includes pull-up transistors PU1′ and PU2′, pull-down transistors PD1′ and PD2′, and pass gate transistors PG1′ and PG2′. The SRAM cell 104b′ includes pull-up transistors PU3′ and PU4′, pull-down transistors PD3′ and PD4′, and pass gate transistors PG3′ and PG4′. For the sake of brevity, similar configurations and connections will not be repeated. The SRAM cells 104a′ and 104b′ include a third and fourth set of cross coupled inverters that each store a data bit. The sources of PG1′ and PG3′ are connected to a second bit line BL2. The sources of PG2′ and PG4′ are connected to a second bit line bar BLB2. The SRAM cell 104a′ share the same first word line WL_A with the SRAM cell 104a, and the SRAM cell 104b′ share the same second word line WL_B with the SRAM cell 104b. That is, the gates of the pass-gate transistors PG1′ and PG2′ also connect to the first word line WL_A, and the gates of the pass-gate transistors PG3′ and PG4′ also connect to the second word line WL_B.

Note that FIG. 2 shows an example embodiment of an SRAM array, but other configurations may be possible. For example, in other embodiments, source and drain nodes of the different pull-up and pull-down transistors may be flipped. Further, the Vdd and Vss nodes may also be flipped. In other words, in some embodiments, high voltage Vdd may connect to source or to drain in any of the pull-up and pull-down transistors of the SRAM array. And in other embodiments, low voltage Vss or ground may connect to source or to drain in any of the pull-up and pull-down transistors of the SRAM array. As such, electrical connections to Vdd and to Vss are herein referred to as power lines, power signal lines, or power line connections that provide routing to power pull-up and pull-down transistors of the memory macro 200 in the device 100.

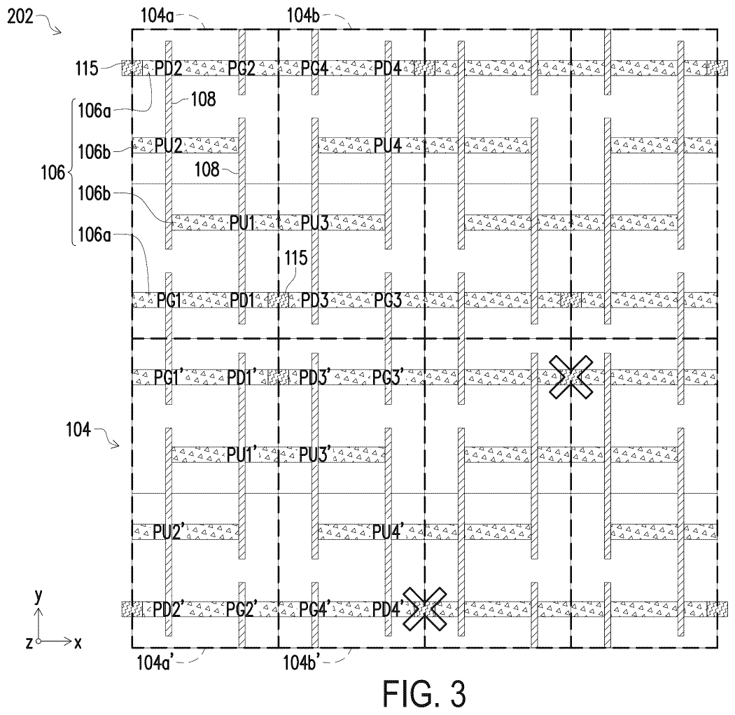

FIG. 3 illustrates a top view device layout 202 of an SRAM array as part of the memory macro 200 in FIG. 1. More specifically the top view device layout 202 corresponds to an SRAM array of eight memory cells 104 (or SRAM cells 104) in a memory cell area 102 of the memory macro 200. The device layout 202 includes the SRAM cells 104a, 104a′, 104b, and 104b′ defined by the dashed line cell boundaries. The SRAM cells 104a, 104a′, 104b, and 104b′ may correspond to the SRAM cells 104a, 104a′, 104b, and 104b′ in FIG. 2. The SRAM cells 104a and 104a′ are adjacent to each other in the y direction and mirror each other across a horizontal cell boundary between them. The SRAM cells 104b and 104b′ are adjacent to each other in the y direction and mirror each other across a horizontal cell boundary between them. The SRAM cells 104a and 104b are adjacent to each other in the x direction and mirror each other across a vertical cell boundary between them. The SRAM cells 104a′ and 104b′ are adjacent to each other in the x direction and mirror each other across a vertical cell boundary between them. As shown, the device layout 202 may include additional SRAM cells 104 adjacent to and mirroring the SRAM cells 104a, 104a′, 104b, and 104b′.

FIG. 3 shows where each of the transistors PU1, PU1′, PU2, PU2′, PU3, PU3′, PU4, PU4′, PD1, PD1′, PD2, PD2′, PD3, PD3′, PD4, PD4′, PG1, PG1′, PG2, PG2′, PG3, PG3′, PG4, and PG4′ are located (labeled on the gate 108 of each transistor). How each transistor is connected to each other has already been described with respect to FIG. 2 and will not be repeated here for the sake of brevity.

The device layout 202 includes several active regions 106 extending along the x direction on a front side of the device 100. The active regions 106 may be configured for planar, fin, or gate-all-around semiconductor structures. In an embodiment, the active regions 106 are fin structures that protrude in the positive z direction from a base substrate. Some of the active regions 106 may extend lengthwise across the vertical cell boundaries so that the same active region is shared across SRAM cells 104. The active regions 106 may include n-type active regions 106a for forming pull-down and pass-gate transistors and p-type active regions 106b for forming pull-up transistors. The p-type active regions 106b extends shorter along the x direction than the n-type active regions 106a. As shown, the p-type active regions 106b is discontinuous and at most spans a length that is less than a width of two SRAM cells 104 along the x direction. On the other hand, the n-type active regions 106a may span continuously in the x direction across the whole memory cell area 102 (shown here as spanning across the whole device layout 202). Several gates 108 are disposed over channel regions of the active regions 106. The channel regions (or transistor channels) refer to portions of the active region 106 directly under a gate 108. The gates 108 extend lengthwise in the y direction. Some of the gates 108 may extend across the horizontal cell boundaries to span across active regions 106 of different SRAM cells.

The device layout 202 further illustrates several backside vias 115 that penetrate and lands on source/drain (S/D) regions of the active regions 106 from a backside of the memory macro 200. S/D regions are regions adjacent the channel regions under the gates 108. The S/D regions and may refer to a source or a drain, individually or collectively dependent upon the context. For n-type active regions 106a, the S/D regions may include epitaxial features doped with n-type dopants such as phosphorous or arsenic. For p-type active regions 106b, the S/D regions may include epitaxial features doped with p-type dopants such as boron. The epitaxial features may be grown from a semiconductor material using a suitable epitaxial growth technique.

The backside vias 115 electrically connect the source (or drain in other embodiments) of the active regions 106 to back side power lines, which then routes to Vss or Vdd. The backside vias 115 includes a suitable metal such as tungsten. In the embodiment shown, the backside vias 115 land on the backsides of source epitaxial features for pull-down transistors (e.g., PD1-PD4 and PD1′-PD4′), which is then routed to Vss. Alternatively, or additionally, the backside vias 115 land on the backsides of source epitaxial features for pull-up transistors (e.g., PU1-PU4 and PU1′-PU4′), which is then routed to Vdd. However, for high density memory cells, the active regions 106 may be too small to consistently form the backside vias 115. For example, when the active regions 106 have widths 10 nm or smaller along the y direction, some of the backside vias 115 may be blocked or not properly formed due to missing or not punching through the S/D regions (as indicated by the X symbols). Therefore, the present disclosure contemplates, in addition to or in lieu of the backside vias 115, providing backside power connections through feedthrough circuits in the edge strap and middle strap areas 400 and 500.

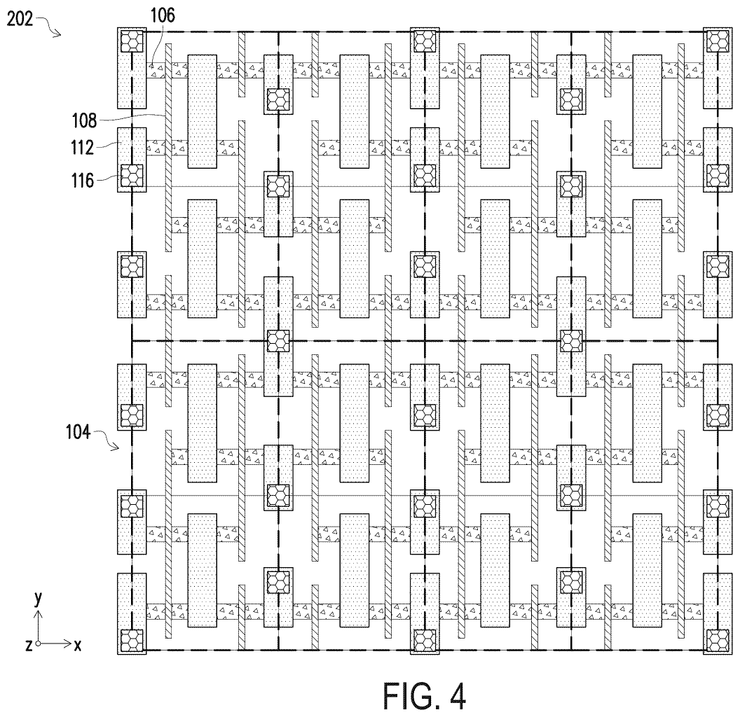

FIG. 4 illustrates a top view device layout 202 showing S/D contacts 112 and S/D vias 116 as part of the memory macro 200 in FIG. 1 (specifically the memory cell area 102). FIG. 4 corresponds to FIG. 3, and the similar features will not be repeated for the sake of brevity. The difference is that FIG. 4 shows S/D contacts 112 and S/D vias 116, and the backside vias 115 from FIG. 3 are filtered out (for simplification). The S/D contacts 112 are disposed over and lands on S/D regions of the active regions 106, some of which are slot contacts that extend in the y direction to couple S/D regions of different transistors together (e.g., a single S/D contact 112 routes the S/D regions of transistors PD1, PD1′, PD3, and PD3′ together). S/D vias 116 are disposed over and lands on the S/D contacts 112. The S/D vias 116 may also be referred to as frontside vias 116 as they are vias formed on a front side of the memory macro 200. The S/D vias 116 (or frontside vias 116) allow the S/D contacts 112 to electrically couple to a higher material layer in the z direction.

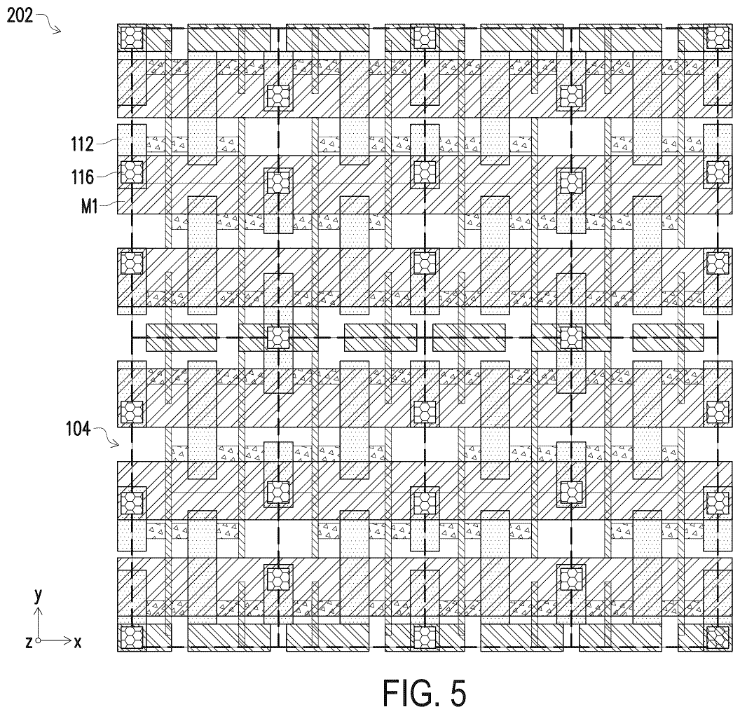

FIG. 5 illustrates a top view device layout 202 showing first metal lines M1 as part of the memory macro 200 in FIG. 1 (specifically the memory cell area 102). FIG. 5 corresponds to FIG. 4, and the similar features will not be repeated for the sake of brevity. The difference is that FIG. 5 shows first metal lines M1 extending lengthwise along the x direction. The first metal lines M1 are disposed over and lands on the frontside vias 116. As shown, some of the first metal lines M1 extend across multiple frontside vias 116 to route a same node connection across multiple SRAM cells 104. These metal lines M1 may route S/D features of several pull-up transistors together or route S/D features of several pass-gate transistors together. Some of the metal lines M1 extend only across a single frontside via 116 to route connection from only a single frontside via 116. These metal lines M1 can still route S/D features of several pull-down transistors together due to the underlying slot S/D contacts 112 coupling multiple S/D regions together. Note that the metal lines M1 that extend only across a single frontside via 116 may have a smaller width in the y direction than the metal lines M1 that extend across multiple frontside vias 116. As shown, there may also be other metal lines M1 that land on and/or couple to the gates 108.

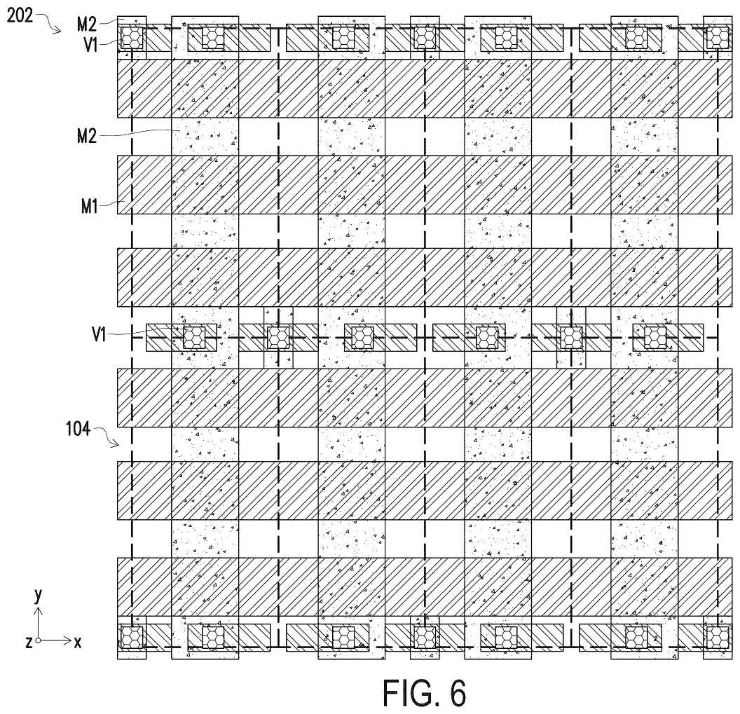

FIG. 6 illustrates a top view device layout 202 showing first interconnect vias V1 and second metal lines M2 as part of the memory macro 200 in FIG. 1 (specifically the memory cell area 102). FIG. 6 corresponds to FIG. 5, and the similar features will not be repeated for the sake of brevity. The difference is that FIG. 6 shows first interconnect vias V1 landing on the first metal lines M1 and second metal lines M2 landing on the first interconnect vias V1. Further, features under the first metal lines M1 (e.g., frontside vias 116, S/D contacts 112, etc.) are filtered out for simplification. The first interconnect vias V1 may have similar dimensions as the frontside vias 116. The first interconnect vias V1 allow the first metal lines M1 to electrically couple to a higher material and metal layer (i.e., the second metal lines M2). The second metal lines M2 extend lengthwise along the y direction over the first interconnect vias V1. As shown, some of the second metal lines M2 extend across multiple first interconnect vias V1 to route a same node connection across multiple SRAM cells 104 (e.g., connecting different gates 108 together to a same node). Some of the second metal lines M2 extend only across a single first interconnect vias V1 to route connection from only a single first interconnect via V1. In the present embodiment, the second metal lines M2 that extend only across a single first interconnect via V1 correspond to metal lines that route to a low voltage Vss or ground node. Although not shown, there may also be second metal lines M2 that correspond to metal lines that route to a high voltage Vdd node. The second metal lines M2 that extend only across a single first interconnect via V1 may have a smaller width in the x direction than the second metal lines M2 that extend across multiple first interconnect vias V1.

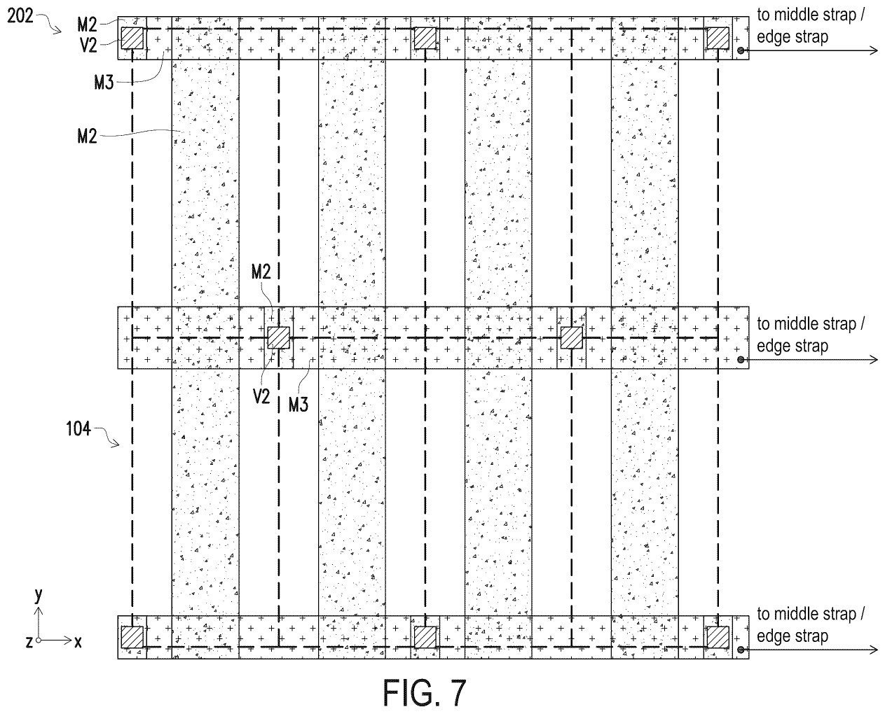

FIG. 7 illustrates a top view device layout 202 showing second interconnect vias V2 and third metal lines M3 as part of the memory macro 200 in FIG. 1 (specifically the memory cell area 102). FIG. 7 corresponds to FIG. 6, and the similar features will not be repeated for the sake of brevity. The difference is that FIG. 7 shows second interconnect vias V2 landing on the second metal lines M2 and third metal lines M3 landing on the second interconnect vias V2. Further, features under the second metal lines M2 (e.g., first interconnect vias V2, first metal lines M1, etc.) are filtered out for simplification. The second interconnect vias V2 may have similar dimensions as the first interconnect vias V1. The second interconnect vias V2 allow the second metal lines M2 to electrically couple to a higher material and metal layer (i.e., the third metal lines M3). The third metal lines M3 extend lengthwise along the x direction over the second interconnect vias V2. As shown, the third metal lines M3 may extend across multiple second interconnect vias V2 to route a same node connection across multiple SRAM cells 104. The present embodiment only shows third metal lines M3 that correspond to metal lines that route to a low voltage Vss or ground node. However, although not shown, there may also be third metal lines M3 that correspond to metal lines that route to a high voltage Vdd node. The third metal lines M3 may continuously extend in the x direction from the memory cell area 102 to the edge and middle strap areas 400 and 500 of the memory macro 200. In other words, the third metal lines M3 are the conduits that couple between the memory cell areas 102 and the edge and middle strap areas 400 and 500.

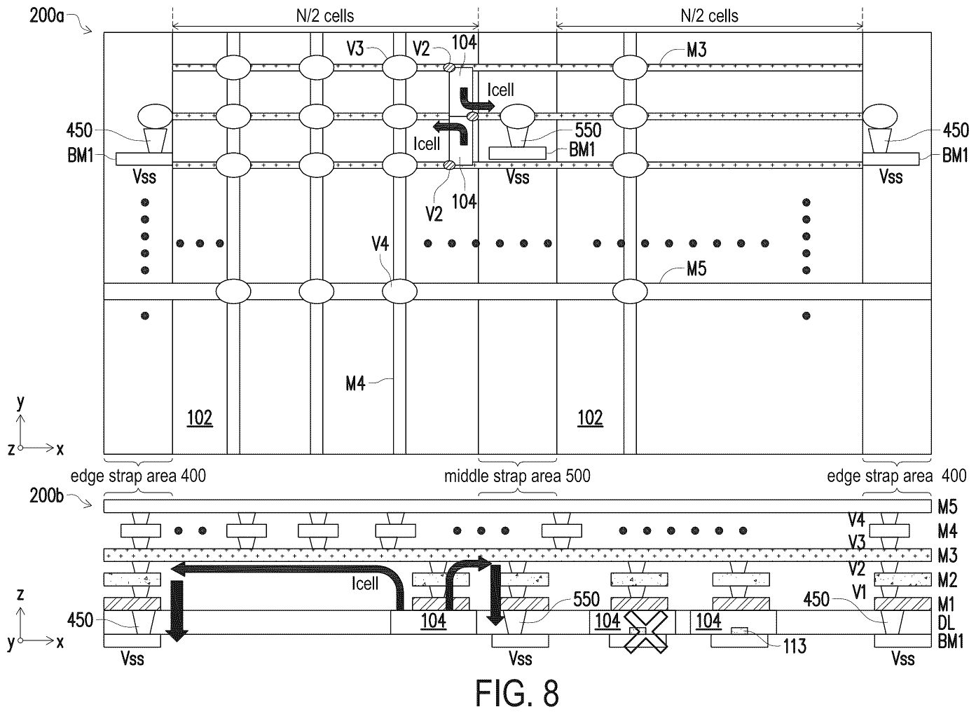

FIG. 8 illustrates a top view 200a and a cross-sectional view 200b of an SRAM circuit area 200 (or memory macro 200). The top and cross-sectional views 200a and 200b are aligned along the x direction, as illustrated by the aligned locations of the corresponding edge strap and middle strap areas 400 and 500. FIG. 8 shows one middle strap area 500 between two edge strap areas 400. The middle strap area 500 divides the memory macro 200 into two memory cell areas 102, each having N/2 cells for storing N/2 bits. N equals to the total number of memory cells 104 or memory bits in the memory macro 200. As shown, the middle strap area 500 creates a shorter Vss (or Vdd) path to backside power lines (e.g., backside metal line BM1) for memory cells 104 closer to the middle of the memory macro 200.

Referring to the top view 200a, the middle memory cells 104 have cell currents Icell that travel to the middle strap area 500 and to the edge strap areas 400 for backside Vss (or Vdd) power connections. The cell current Icell is improved by the additional and closer route provided by the middle strap area 500. In the present embodiment, the cell current Icell may flow from second interconnect vias V2 (such as those described in FIG. 7) to third metal lines M3, where the third metal lines M3 extends in the x direction to the edge and middle strap areas 400 and 500. The third metal lines M3 are then electrically coupled to feedthrough circuits 450 and 550 at the edge and middle strap areas 400 and 500. The feedthrough circuits 450 and 550 then land on backside metal lines BM1 for back side power routing. The backside metal lines BM1 is disposed on a back surface of the memory macro 200. The top view 200a further illustrates metal lines M4 and M5 over the metal lines M3. The metal lines M4 extend lengthwise along the y direction and connects to the metal lines M3 through third interconnect vias V3 therebetween. The metal lines M5 extend lengthwise along the x direction and connects to the metal lines M4 through fourth interconnect vias V4 therebetween. The metal lines M4 and M5 may further route power signals to higher-level interconnects and to even higher-level redistribution layers and bonding pads at the frontside of the memory macro 200.

Referring to the cross-sectional view 200b, the memory macro 200 includes a device layer DL where device-level features of the memory cells 104 are formed. The device layer DL includes the active regions 106, the gates 108, the S/D contacts 112, and the frontside vias 116. The device layer DL also includes and embeds feedthrough circuits 450 and 550 that penetrates through the device layer DL for direct connection to backside metals such as a backside metal line BM1. The backside metal lines BM1 may be electrically connected to Vss as shown, or to Vdd in other embodiments. The first metal lines M1 are disposed over the device layer (DL) such as landing on the frontside vias 116 in the memory cells 104 and on the feedthrough circuits 550. The first interconnect vias V1 land on the first metal lines M1. The second metal lines land on the first interconnect vias V1. The second interconnect vias V2 land on the second metal lines M2. The third metal lines M3 land on the second interconnect vias V2. The third metal lines M3 are electrically connected to the feedthrough circuits 450 and 550 at the edge and middle strap areas 400 and 500 through the second interconnect vias V2, the second metal lines M2, the first interconnect vias V1, and the first metal lines M1. The third interconnect vias V3 land on the third metal lines M3. The fourth metal lines M4 land on the third interconnect vias V3. The fourth interconnect vias V4 land on the fourth metal lines M3. And the fifth metal lines M5 land on the fourth interconnect vias V4. Additional frontside metal lines and interconnect vias may be formed over the fifth metal lines M5 (not shown) to form a frontside interconnect structure. A passivation structure (not shown) having redistribution layers and bonding pads may be formed over the frontside interconnect structure.

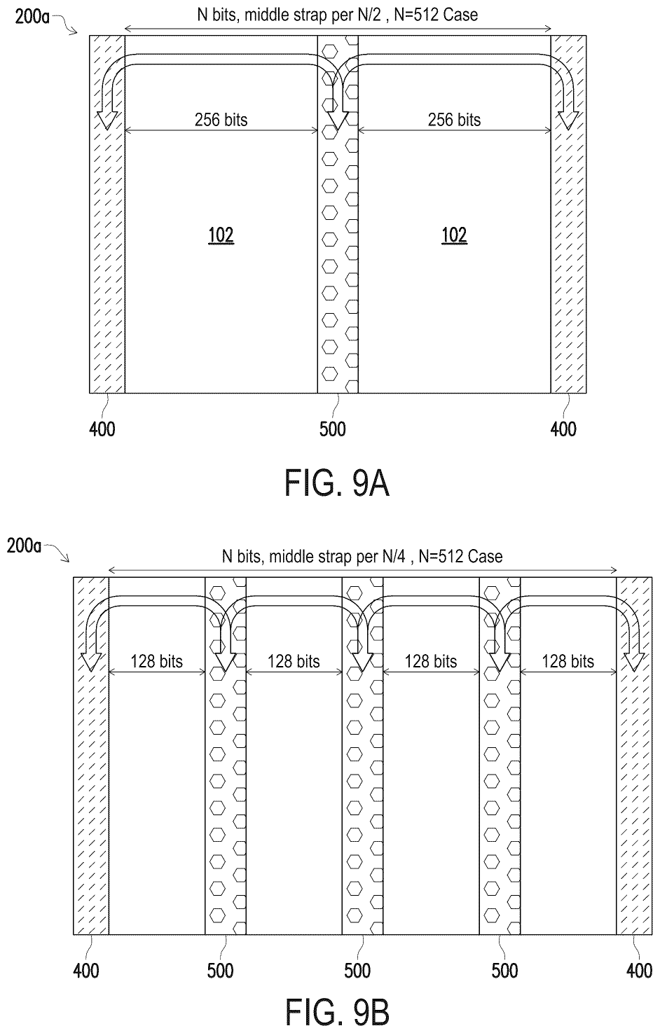

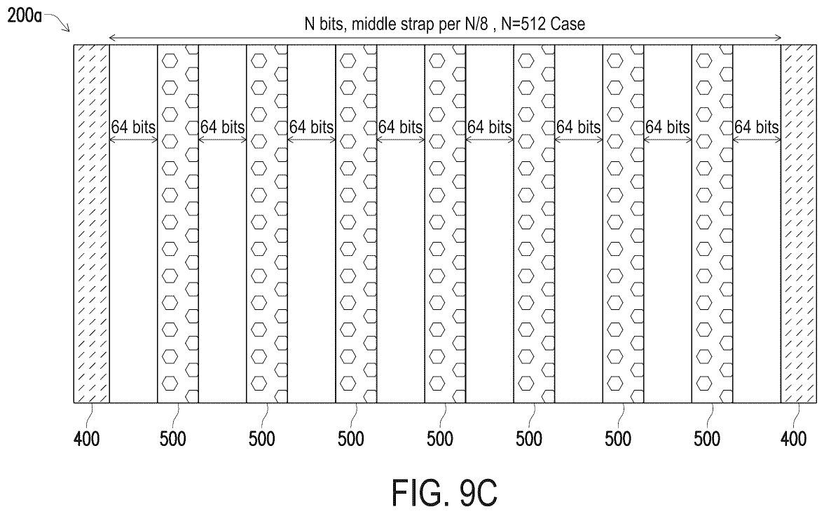

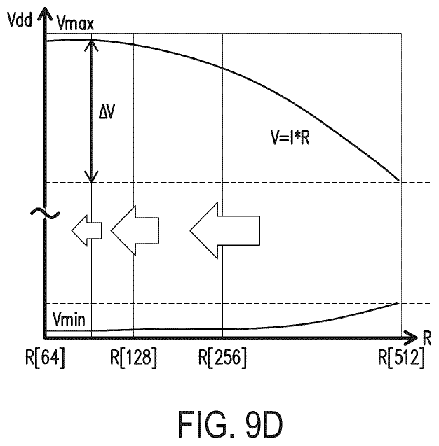

FIGS. 9A-9C illustrate a top view 200a of an SRAM circuit area 200 (or memory macro 200) with even number of domains between strap areas, which include edge and/or middle strap areas 400 and 500. Referring to the embodiment in FIG. 9A, the memory macro 200 has N bits where N is 512. In this case, there is a middle strap area 500 per N/2 bits (i.e., 256 bits), resulting in a single middle strap area 500 between edge strap areas 400. As shown, the memory macro 200 is divided into two domains of memory cell areas 102. Each memory cell area 102 has 256 memory bits disposed between an edge strap area 400 and a middle strap area 500. Referring to the embodiment in FIG. 9B, the memory macro 200 also has N bits where N is 512. In this case, there is a middle strap area 500 per N/4 bits (i.e., 128 bits), resulting in three middle strap areas 500 between edge strap areas 400. As shown, the memory macro 200 is divided into four domains of memory cell areas 102. Each memory cell areas 102 is disposed between an edge strap area 400 and a middle strap area 500, or between two middle strap areas 500. Referring to the embodiment in FIG. 9C, the memory macro 200 also has N bits where N is 512. In this case, there is a middle strap area 500 per N/8 bits (i.e., 64 bits), resulting in seven middle strap areas 500 between edge strap areas 400. As shown, the memory macro 200 is divided into eight domains of memory cell areas 102. Each memory cell areas 102 is disposed between an edge strap area 400 and a middle strap area 500, or between two middle strap areas 500. Note that the present embodiments define the memory macro 200 to have N bits where N is 512. However, N may be any other number (e.g., 256, 1024) depending on design requirements.

FIG. 9D illustrates a graph showing improvements to voltage drop depending on the number of domains in an SRAM circuit area 200 (or memory macro 200). As demonstrated in FIGS. 9A-9B, as the number of domains increase by adding more middle strap areas 500, the memory bits in each domain decreases (e.g., from 512 to 64). As memory bits in each domain decrease, resistance is reduced due to shorter current route to Vss and/or Vdd. As resistance is reduced, voltage drop in the Vss and/or Vdd current path is minimized, thereby maximizing Vmax for improved cell current performance. For example, in the case where N=512 and there is no middle strap area 500: there is only one domain having 512 bits. In this case, the resistance is the highest causing the worst Vmax. In the case where N=512 and there is one middle strap area 500: there are two domains each having 256 bits. In this case, the resistance is lower and the Vmax is higher than the one domain case. In the case where N=512 and there are three middle strap areas 500: there are four domains each having 128 bits. In this case, the resistance is lower and the Vmax is higher than the two domains case. In the case where N=512 and there are seven middle strap areas 500: there are eight domains each having 64 bits. In this case, the resistance is lower and the Vmax is higher than the four domains case. At some point, adding more middle strap areas 500 have diminished returns as the Vmax approaches the ideal Vdd.

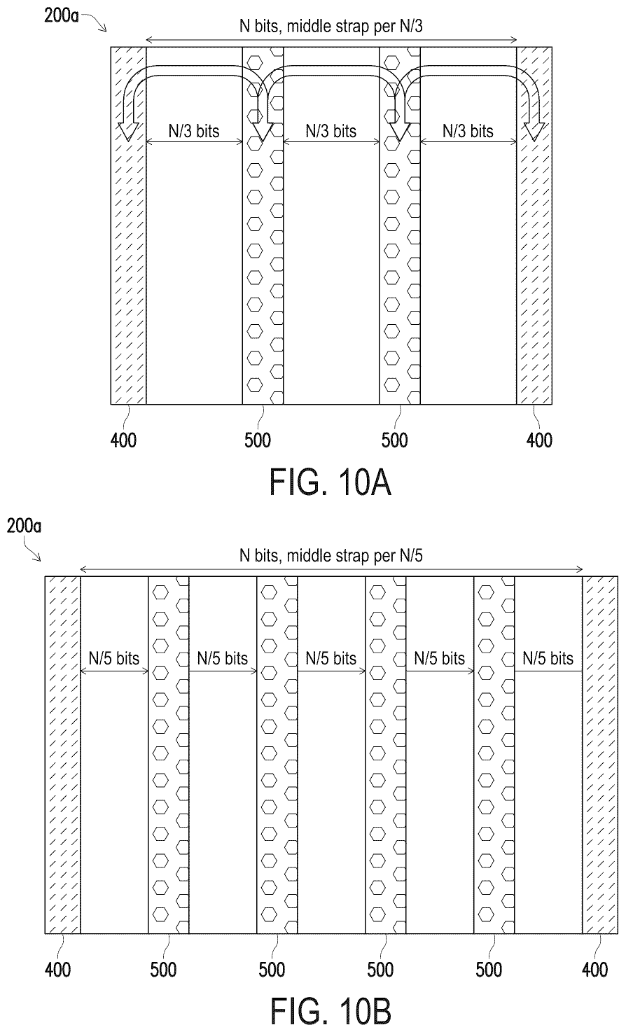

FIGS. 10A-10B illustrate a top view 200a of an SRAM circuit area 200 (or memory macro 200) with odd number of domains between strap areas, which include edge and/or middle strap areas 400 and 500. Referring to the embodiment in FIG. 10A, the memory macro 200 has N bits having a middle strap area 500 per N/3 bits, resulting in three domains and two middle strap areas 500 between edge strap areas 400. Note that depending on the number N, each of the three domains may not have exactly the same number of bits. Referring to the embodiment in FIG. 10B, the memory macro 200 has N bits having a middle strap area 500 per N/5 bits, resulting in five domains and four middle strap areas 500 between edge strap areas 400. Note that depending on the number N, each of the five domains may not have exactly the same number of bits. Other odd number of domains is possible for any given N bits, where the number of middle strap areas 500 would be one less the number of domains. For example, given Q domains that evenly (or substantially evenly) divide N bits, there are Q minus one middle strap areas 500.

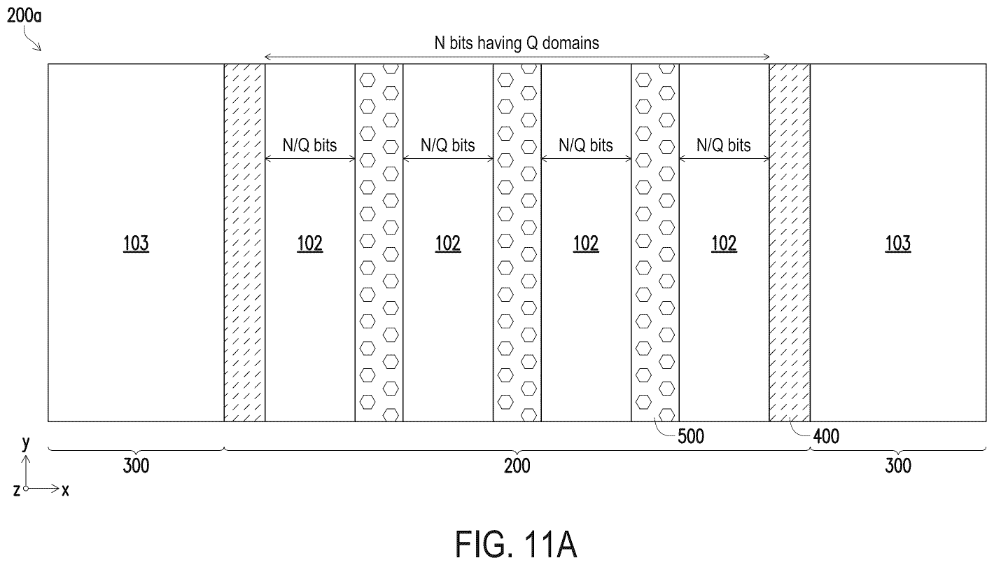

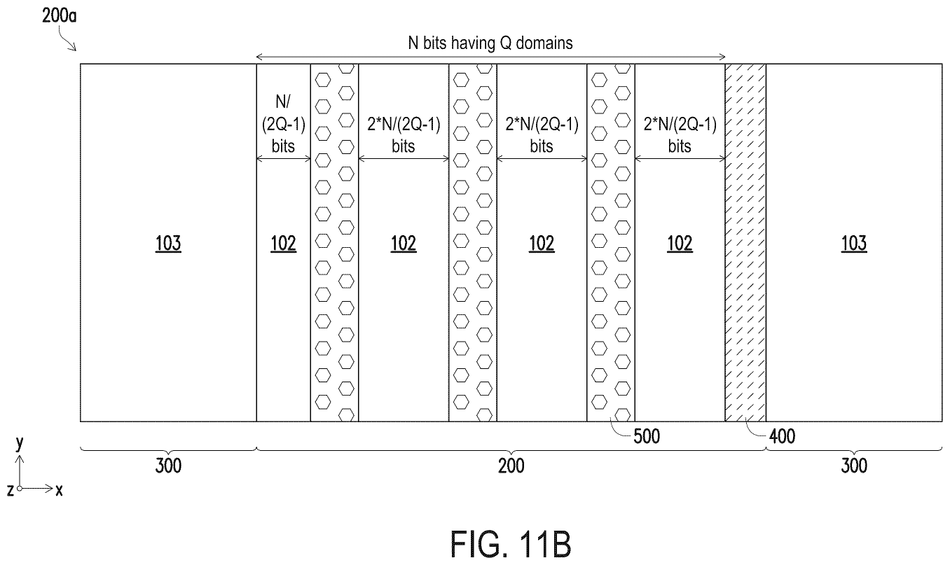

FIG. 11A illustrates a top view 200a of an IC structure (or device 100) having an SRAM circuit area 200 (or memory macro 200) with two edge strap areas 400. The memory macro 200 comprises N bits implemented by N memory cells 104. And the memory macro 200 comprises Q domains implemented by Q memory cell areas 102. The Q memory cell areas 102 are separated from each other by middle strap areas 500. Each domain may include N/Q bits. In the embodiment shown, there are two edge strap areas 400. One edge of each of the edge strap areas 400 is directly adjacent the memory cell areas 102 along the x direction. The other edge of each of the edge strap areas 400 is directly adjacent the logic cell areas 103 of the logic circuits 300 along the x direction. As such, each of the logic cell areas 103 is isolated from a memory cell area 102 by the edge strap areas 400. In the present embodiment, each of the edge strap areas 400 spans a width along the x direction from a memory cell area 102 to a logic cell areas 103, and each of the middle strap areas 500 spans a width along the x direction between memory cell areas 102. As described previously, both the edge and middle strap areas 400 and 500 provide backside power routing for memory cells 104 in the memory cell area 102. However, the edge strap areas 400 may additionally provide backside power routing for the logic cells in the logic cell areas 103.

FIG. 11B illustrates a top view 200a of an IC structure (or device 100) having an SRAM circuit area 200 (or memory macro 200) with one edge strap area 400. FIG. 11B is similar to FIG. 11A and the similar features will not be described again for the sake of brevity. The difference is that there is only one edge strap area 400 instead of two. As shown, on one extreme end of the memory macro 200 there is an edge strap area 400, while on the opposite extreme end of the memory macro 200 there is no edge strap area 400. In this configuration, at one end of the memory macro 200, a memory cell area 102 directly abuts a logic cell area 103 without an intervening edge strap area 400. Except for the domain directly abutting the logic circuit 300, each domain may include 2*N/(2Q−1) bits, and the domain directly abutting the logic circuit 300 may include N/(2Q−1) bits. In other words, the domain directly abutting the logic circuit 300 may be half the size the domains not directly abutting the logic circuit 300.

Still referring to FIG. 11A, a middle strap area 500 at the very end of one side of the memory macro 200 provides backside power routing to the memory cell area 102 directly abutting a logic cell area 103. Acting as an edge strap for the logic cell area 103, this same middle strap area 500 may also provide backside power routing to the logic cell area 103 itself. As such, at this end of the memory macro, no edge strap area 400 is needed. However, if the domain directly abutting the logic circuit 300 is too big (i.e., approaching the size of the other domains), a separate edge strap area 400 may be necessary to ensure adequate provision of power routing. This is the reason why the domain directly abutting the logic circuit 300 should be smaller than the other domains, such as half or even smaller than half the size the domains not directly abutting the logic circuit 300.

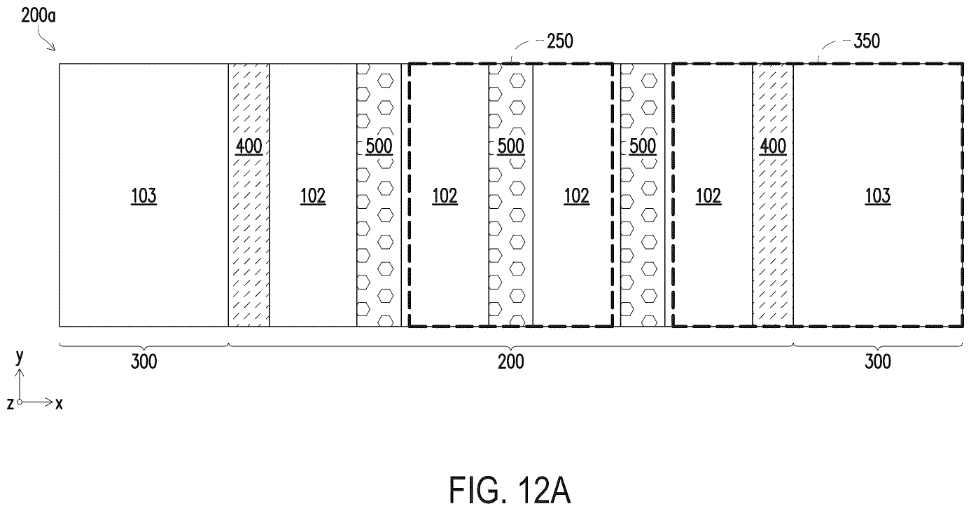

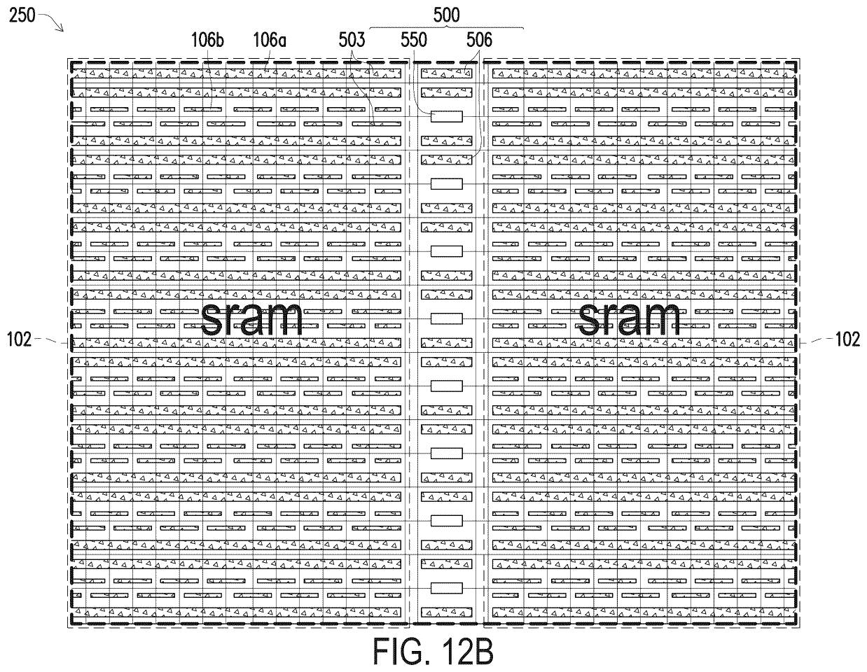

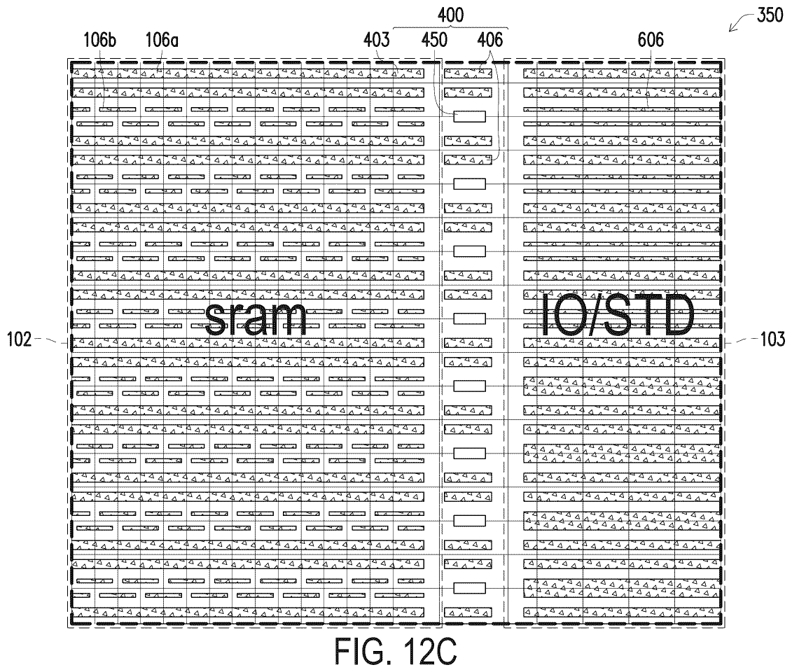

FIG. 12A illustrates a top view 200a of an IC structure (or device 100) having an SRAM circuit area 200 (or memory macro 200) with multiple middle strap areas 500 between edge strap areas 400. FIG. 12A also illustrates logic circuits 300 adjacent the memory macro 200. FIG. 12A resembles FIG. 11A and the similar features will not be described again for the sake of brevity. The difference is that FIG. 12A illustrates a first interface region 250 and a second interface region 350 denoted by the respective dashed boxes. The first interface region 250 includes a middle strap area 500 between memory cell areas 102. The second interface region 350 includes an edge strap area 400 between a memory cell area 102 and a logic cell area 103.

FIG. 12B illustrates a zoomed-in top view of the first interface region 250 in FIG. 12A. As shown in FIG. 12B, the middle strap area 500 spans between SRAM memory cell areas 102. Each of the SRAM memory cell areas 102 includes n-type active regions 106a that continuously extends lengthwise along the x direction across the entirety of the respective memory cell areas 102. Each of the SRAM memory cell areas 102 includes p-type active regions 106b that extend discontinuously along the x direction across the memory cell areas 102 (i.e., p-type active regions 106b are isolated from each other along the x direction across memory cell areas 102). Further, the n-type active regions 106a may have a greater width along the y direction than the p-type active regions 106b. Note that some of the n-type active regions 106a and p-type active regions 106b extend into a buffer region of the middle strap area 500. These n-type and p-type active regions 106a and 106b do not form transistor devices and act as dummy extensions 503.

Still referring to FIG. 12B, the middle strap area 500 may further include dummy n-type active regions 506 that also do not form transistor devices. These dummy n-type active regions 506 are aligned in the x direction with the dummy extensions 503. However, the dummy n-type active regions 406 are separated from the dummy extensions 503 to form isolated active regions. Further, the middle strap areas 500 includes feedthrough circuits 550 between the dummy n-type active regions 506 along the y direction. The feedthrough circuits 550 provide vertical metal routing to a backside of the memory macro 200. The feedthrough circuits 550 are also disposed between buffer regions of the middle strap areas 500 along the x direction. The buffer regions include the dummy extensions 503 described above.

FIG. 12C illustrates a zoomed-in top view of the second interface region 350 in FIG. 12A. FIG. 12C include features similar to FIG. 12B, and the similar features will not be described again for the sake of brevity. The difference is showing an edge strap area 400 between an SRAM memory cell area 102 and a logic cell area 103. The logic cell area 103 may include input/output (IO) and/or standard cell (STD) transistors for performing logic functions. The logic cell area 103 include logic cell active regions 606 that all continuously extends lengthwise along the x direction across the entirety the logic cell areas 103. The logic cell active regions 606 may be n-type, p-type, or a combination of n-type and p-type to form logic transistors. The edge strap area 400 include similar features as the middle strap areas 500. For example, the edge strap area 400 includes feedthrough circuits 450 between dummy n-type active regions 406 along the y direction. The feedthrough circuits 450 provide vertical metal routing to a backside of the memory macro 200. The feedthrough circuits 450 are disposed between buffer regions of the edge strap area 400 along the x direction. The buffer regions include dummy extensions 403 extending from the memory cell areas 102. In some embodiments (like as shown), there is only one buffer region along the side of the memory cell area 102. In this case, there is no buffer region along the side of the logic cell area 103.

Still referring to FIG. 12C, as previously described, the edge strap area 400 may have a smaller width along the x direction than the middle strap areas 500. For example, while the sizes of the feedthrough circuits 450 and 550 may be similar, the buffer regions in the middle strap areas 500 that surround the feedthrough circuit 550 may be greater than the buffer regions in the edge strap areas 400 that surround the feedthrough circuit 450. This may be due to a smaller buffer region between the feedthrough circuit 450 and the logic cell areas 103 when compared to the buffer region between the feedthrough circuit 450 and the memory cell area 102. Whereas in the case of the middle strap areas 500, both sides of the middle strap area 500 has the bigger buffer region between the feedthrough circuit 550 and the memory cell areas 102. In some embodiments (like as shown), for the edge strap areas 400, there are no buffer regions on the side of the edge strap area 400 adjacent logic cell areas 103.

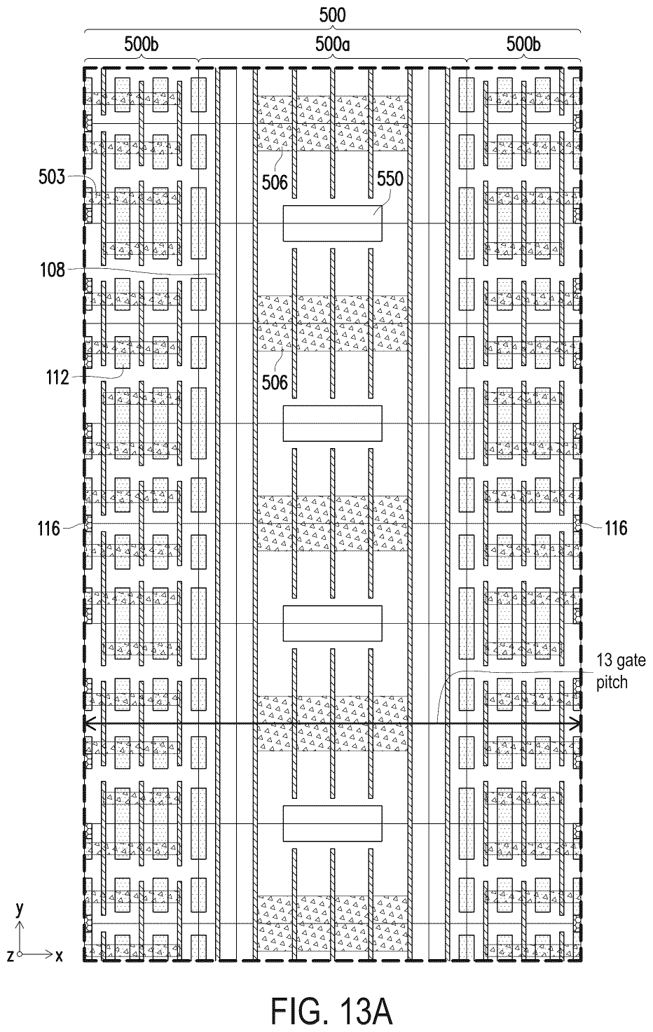

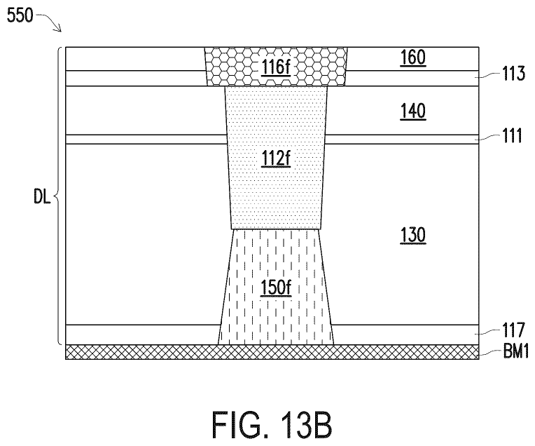

FIG. 13A illustrates a top view of a middle strap area 500 in an SRAM circuit area 200 (or memory macro 200). In the embodiment shown, the middle strap area 500 includes a feedthrough circuit region 500a sandwiched between buffer regions 500b along the x direction. The feedthrough circuit region 500a includes feedthrough circuits 550 disposed between dummy n-type active regions 506 along the y direction. The buffer regions 500b include dummy extensions 503 extending from n-type and p-type active regions 106a and 106b in the memory cell areas 102. FIG. 13A also illustrate other device level features such as gates 108 extending lengthwise along the y direction, S/D contacts 112 disposed over S/D regions of the dummy extensions 503, and frontside vias 116 landing on some of the S/D contacts 112 at the edges of the middle strap area 500. As shown in FIG. 13A, the frontside vias 116 define the edge boundaries of the middle strap area 500. This is because these frontside vias 116 define where the memory cell areas 102 begin.

Still referring to FIG. 13A, the middle strap area 500 may span a width of 13 gate pitches, where a gate pitch is a distance between gates 108 along the x direction. The feedthrough circuit region 500a may span 7 gate pitches while each of the buffer regions 500b may span 3 gate pitches, adding up to a total of 13 gate pitches. Whereas an edge strap area 400 (not shown) may only span a width of 10 gate pitches. An edge strap area 400 may be configured similarly to the middle strap area 500, but instead of having two buffer regions, there is only one. For example, the edge strap area 400 may have a feedthrough circuit region that spans 7 gate pitches and a single buffer region that spans 3 gate pitches, adding up to a total of 10 gate pitches. In this case, the edge strap area 400 only has a buffer region bordering the memory cell area 102, and no buffer region bordering a logic cell area 103.

FIG. 13B illustrates a cross-sectional view of a feedthrough circuit 550 of the middle strap area 500 in FIG. 13A. FIG. 13B shows a device layer DL having various interlayer dielectric (ILD) layers 130, 140, and 160, etch stop layers 111, 113, and 117, and/or backside hard mask layers 117 that embed metal features. The metal features make up the feedthrough circuit 550, and the metal features may include a feedthrough via 150f penetrating from a backside of the memory macro 200 through a first portion of the device layer DL, a feedthrough contact 112f penetrating from a frontside of the memory macro 200 through a second portion of the device layer DL, and a feedthrough frontside via 116f penetrating from a frontside of the memory macro 200 through a third portion of the device layer DL. In the embodiment shown, the feedthrough via 150f may penetrate through one or more backside hard mask layers 117 and a portion of the ILD layer 130. The feedthrough via 150f lands on a backside metal line BM1 disposed on a back surface of the device layer DL. The backside metal line BM1 may be part of a backside metal interconnect structure (not shown), which includes additional stacked backside metals vertically connected by additional backside interconnect vias for backside power signal routing (e.g., Vss or Vdd). The feedthrough contact 112f may penetrate through the ILD layer 140, the etch stop layer 111, and a portion of the ILD layer 130 to land on a top surface of the feedthrough via 150f. The feedthrough frontside via 116f may penetrate through the ILD layer 160 and the etch stop layer 113 to land on a top surface of the feedthrough contact 112f.

The etch stop layers 111, 113, and hard mask layer(s) 117 may include different dielectric materials from the ILD layers 130, 140, and 160 for etchant selectivity. For example, the etch stop layers 111, 113, and hard mask layer(s) 117 include a nitride-based dielectric such as silicon nitride, silicon oxynitride, silicon carbonitride, silicon carbon oxynitride, or combinations thereof. And the first, second, and third ILD layers 130, 140, and 160 include silicon oxide or an oxide-based dielectric formed with tetraethylorthosilicate, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof.

Still referring to FIG. 13B, the device layer DL may correspond to the device layer DL described in FIG. 8. As such, features in the feedthrough circuit 550 may be compared to features in other areas such as the memory cell areas 102. In the embodiment shown, the top surface of the feedthrough contact 112f may be substantially coplanar with the top surface of the S/D contacts 112 previously described. The etch stop layer 111 may land on a top surface of the gates 108 previously described. The top surface of the feedthrough frontside via 116f may be substantially coplanar with the top surface of the frontside vias 116 previously described. And the ILD layer 130 may embed and be disposed over the active regions 106 previously described.

Although not limiting, the present disclosure offers advantages for backside power routing for semiconductor devices such as SRAM devices. One example advantage is integrating middle strap areas within memory macro areas to route power lines directly to the back side of an SRAM device. Another example advantage is utilizing both backside vias and middle strap areas for dual side power routing. Another example advantage is eliminating edge strap areas in the memory macro and allowing a middle strap area to provide necessary power routing to both memory and logic cells.

One aspect of the present disclosure pertains to a device. The device includes a memory macro having a frontside and a backside along a vertical direction. The memory macro includes edge strap areas extending lengthwise along a first direction at edges of the memory macro, a memory cell area having a plurality of memory cells, where the memory cell area is disposed between the edge strap areas along a second direction perpendicular to the first direction, and a middle strap area extending lengthwise along the first direction and disposed between the edge strap areas along the second direction, where the middle strap area divides the memory cell area into two memory cell domains. The middle strap area includes a feedthrough circuit that routes a power signal line of one of the plurality of memory cells to the backside of the memory macro.

In an embodiment, the power signal line is connected to a high voltage power supply Vdd or to a low voltage power supply Vss.

In an embodiment, the edge strap areas also include feedthrough circuits that routes the power signal line of the one of the plurality of memory cells to the backside of the memory macro.

In an embodiment, the device further includes a logic circuit area adjacent the memory macro, wherein the logic circuit area is isolated from the memory cell area by one of the edge strap areas. In a further embodiment, the one of the edge strap areas spans between the memory macro and the logic circuit area, and the middle strap area spans a greater width along the second direction than the edge strap areas.

In an embodiment, the device further includes a backside metal line disposed on the backside of the memory macro, wherein a feedthrough via of the feedthrough circuit lands on the backside metal line.

In an embodiment, the power signal line of the one of the plurality of memory cells includes: a source/drain (S/D) contact landing on an S/D feature in the one of the plurality of memory cells; a frontside via landing on the S/D contact; a first metal line landing on the frontside via; a first interconnect via landing on the first metal line; a second metal line landing on the first interconnect via; a second interconnect via landing on the second metal line; and a third metal line landing on the second interconnect via, wherein the third metal line lands on a metal feature of the feedthrough circuit in the middle strap area.

In a further embodiment, the device further includes a backside metal line disposed on the backside of the memory macro, where the metal feature of the feedthrough circuit includes: a feedthrough via landing on the backside metal line; a feedthrough contact landing on the feedthrough via; a feedthrough frontside via landing on the feedthrough contact; a first feedthrough metal line landing on the feedthrough frontside via; a first feedthrough interconnect via landing on the first feedthrough metal line; a second feedthrough metal line landing on the first feedthrough interconnect via; and a second feedthrough interconnect via landing on the second feedthrough metal line, where the third metal line lands on the second feedthrough interconnect via.

In a further embodiment, the power signal line of the one of the plurality of memory cells further includes: a third interconnect via landing on the third metal line; and a fourth metal line landing on the third interconnect via, where the fourth metal line further routes the power signal line to higher level metal lines over the frontside of the memory macro.

In an embodiment, the memory cell area has 512 SRAM cells, and each of the two memory cell domains has 256 SRAM cells.

In an embodiment, the middle strap area is a first middle strap area, and the memory macro further includes additional middle strap areas extending lengthwise along the first direction and disposed between the edge strap areas along the second direction, the additional middle strap areas divides the memory cell area into additional memory cell domains, where each of the additional middle strap areas include a feedthrough circuit that routes a power signal line of one of the plurality of memory cells to the backside of the memory macro.

Another aspect of the present disclosure pertains to a device. The device includes a memory macro having a frontside and a backside along a vertical direction, wherein the memory macro includes: a memory cell area having a plurality of memory cells, an edge strap area adjacent a first side of the memory cell area, the edge strap area extending lengthwise along a first direction at an edge of the memory macro, and a middle strap area within the memory cell area, the middle strap area extending lengthwise along the first direction. The middle strap area divides the memory cell area into two memory cell domains. The middle strap area includes a feedthrough circuit that routes a power signal line of one of the plurality of memory cells to a backside of the memory macro. The middle strap area spans a first width along a second direction perpendicular to the first direction, the edge strap area spans a second width along the second direction, the first width is a distance between the two memory cell domains, and the first width is greater than the second width.

In a further embodiment, the device further includes a first logic circuit area adjacent a first side of the memory macro, where the first logic circuit area is isolated from the memory cell area by the edge strap area; and a second logic circuit adjacent a second side of the memory macro, where the second logic circuit directly abuts the memory cell area without an intervening edge strap area.

In a further embodiment, the edge strap area is a first edge strap area, and the device further includes further includes: a second edge strap area adjacent a second side of the memory cell area, the second edge strap area extending lengthwise along the first direction at a second edge of the memory macro; a first logic circuit area adjacent a first side of the memory macro, where the first logic circuit area is isolated from the memory cell area by the first edge strap area; and a second logic circuit area adjacent a second side of the memory macro, where the second logic circuit area is isolated from the memory cell area by the second edge strap area.

In an embodiment, the power signal line is connected to a high voltage power supply VDD or to a low voltage power supply VSS. In an embodiment, the middle and edge strap areas do not include memory cells.

Another aspect of the present disclosure pertains to a device. The device includes a memory macro having a plurality of memory cells, the memory macro having a frontside and a backside; a middle strap area disposed between two memory cells of the plurality of memory cells, the middle strap area includes a vertical metal routing that electrically connect to a power signal line of one of the plurality of memory cells to a backside of the memory macro; edge strap areas on edges of the memory macro, where the middle strap area is between the edge strap areas, where the edge strap areas also include vertical metal routing that electrically connect a power signal line of the one of the plurality of memory cells to a backside of the memory macro; and logic circuit areas adjacent the memory macro, the logic circuit areas having a plurality of logic cells adjacent the edge strap areas, where the logic cells and the memory cells have active regions with different configurations.

In an embodiment, in the memory cells, the active regions for p-type transistors and n-type transistors extend lengthwise along a first direction at different lengths, and in the logic cells, active regions for p-type transistors and n-type transistors extend lengthwise along the first direction at same lengths.

In an embodiment, the edge strap areas span between the memory macro and the logic circuit areas, and the middle strap area spans a greater width along the second direction than the edge strap areas.

In an embodiment, the middle strap area is a first middle strap area, and the memory macro further includes additional middle strap areas extending lengthwise along a first direction and disposed between the edge strap areas, each of the additional middle strap areas are disposed between additional two memory cells of the plurality of memory cells, each of the middle strap areas includes a vertical metal routing that electrically connect a power signal line of one of the plurality of memory cells to the backside of the memory macro.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a memory macro having a frontside and a backside along a vertical direction, wherein the memory macro includes:
a first memory area having a first array of memory bit cells, the first array extending widthwise along a first direction and lengthwise along a second direction different from the first direction;
a second memory area having a second array of memory bit cells, the second array extending widthwise along the first direction and lengthwise along the second direction; and
a middle strap area extending widthwise between the first and the second memory areas along the first direction, wherein the middle strap area is without any memory bit cells and extends lengthwise along the second direction to separate the first memory area from the second memory area,
wherein the middle strap area includes a feedthrough circuit that routes a power signal line of one or more of the memory bit cells in the first or the second memory areas from the frontside to the backside of the memory macro.

2. The device of claim 1,
wherein the memory macro further includes an edge strap area extending widthwise along the first direction at an edge of the memory macro, wherein the edge strap area is without any memory bit cells and extends lengthwise parallel to the middle strap area along the second direction,
wherein the edge strap area includes another feedthrough circuit that routes another power signal line of one or more of the memory bit cells in the first or the second memory areas from the frontside to the backside of the memory macro.

3. The device of claim 2, further comprising:
a logic circuit area adjacent the memory macro, wherein the logic circuit area is isolated from the first or the second memory areas by the edge strap area.

4. The device of claim 1, wherein the power signal line is connected to a high voltage power supply Vdd or to a low voltage power supply Vss.

5. The device of claim 1, wherein the memory macro includes 512 memory bits implemented by arrays of 256 bit cells in each of the first and the second memory areas.

6. The device of claim 1, further comprising:
a backside metal line disposed on the backside of the memory macro, wherein a feedthrough via of the feedthrough circuit lands on the backside metal line.

7. The device of claim 1, wherein the power signal line of the one of the one or more of the memory bit cells includes:
a source/drain (S/D) contact landing on an S/D feature in the one or more of the memory bit cells; and
a metal line electrically connected to the S/D contact and extending lengthwise along the first direction from the first or the second memory areas to land on a metal feature of the feedthrough circuit in the middle strap area.

8. The device of claim 1, wherein along the first direction, the middle strap area includes the feedthrough circuit sandwiched between buffer regions, wherein the buffer regions include dummy extensions of active regions that continuously extend from the first and the second memory cells.

9. The device of claim 1, wherein the middle strap area spans a width of 13 gate pitches, wherein a gate pitch is a distance between dummy gates in the middle strap area along the first direction.

10. The device of claim 1, wherein the memory macro includes additional middle strap areas that separate the first and the second memory areas from additional memory areas, respectively, wherein the additional middle strap areas each include a feedthrough circuit that routes a power signal line of one or more of the memory bit cells in the additional memory areas from the frontside to the backside of the memory macro.

11. A device, comprising:
a memory macro having a frontside and a backside along a vertical direction, wherein the memory macro includes:
a memory cell area having a plurality of memory cells,
an edge strap area adjacent a first side of the memory cell area, the edge strap area extending lengthwise along a first direction at an edge of the memory macro, and
a middle strap area within the memory cell area, the middle strap area extending lengthwise along the first direction, wherein the middle strap area divides the memory cell area into two memory cell domains and the middle strap area includes a feedthrough metal feature that routes a power signal line of one of the plurality of memory cells from the frontside of the memory macro to the backside of the memory macro.

12. The device of claim 11, wherein the middle strap area spans a first width along a second direction perpendicular to the first direction, the edge strap area spans a second width along the second direction, and the first width is greater than the second width.

13. The device of claim 11, wherein the power signal line includes:
a stack of first frontside metal features electrically connected to an S/D feature in the one of the plurality of memory cells;
a stack of second frontside metal features electrically connected to the feedthrough metal feature; and
a metal line extending from the memory cell area to the middle strap area to electrically connect the stack of first frontside metal features to the stack of second frontside metal features.

14. The device of claim 11, wherein the feedthrough metal feature is a first feedthrough metal feature, further comprising:
a second feedthrough metal feature in the edge strap area that routes a power signal line of another one of the plurality of memory cells from a frontside of the memory macro to a backside of the memory macro.

15. The device of claim 14, wherein the power signal line of the another one of the plurality of memory cells includes:
a stack of first frontside metal features electrically connected to an S/D feature in the another one of the plurality of memory cells;
a stack of second frontside metal features electrically connected to the second feedthrough metal feature; and
a metal line extending from the memory cell area to the edge strap area to electrically connect the stack of first frontside metal features to the stack of second frontside metal features.

16. The device of claim 11, further comprising:
a first logic circuit area adjacent a first side of the memory macro, wherein the first logic circuit area is isolated from the memory cell area by the edge strap area; and
a second logic circuit adjacent a second side of the memory macro, wherein the second logic circuit directly abuts the memory cell area without an intervening edge strap area.

17. The device of claim 12, wherein the edge strap area is a first edge strap area, further comprising:
a second edge strap area adjacent a second side of the memory cell area, the second edge strap area extending lengthwise along the first direction at a second edge of the memory macro;
a first logic circuit area adjacent a first side of the memory macro, wherein the first logic circuit area is isolated from the memory cell area by the first edge strap area; and
a second logic circuit area adjacent a second side of the memory macro, wherein the second logic circuit area is isolated from the memory cell area by the second edge strap area.

18. A device, comprising:
a memory macro having a plurality of memory cells, the memory macro having a frontside and a backside;
a middle strap area disposed between two memory cells of the plurality of memory cells, the middle strap area includes a vertical metal routing that electrically connect a power signal line of one of the plurality of memory cells from the frontside to the backside of the memory macro; and
logic circuit areas adjacent the memory macro, the logic circuit areas having a plurality of logic cells, wherein the logic cells and the memory cells have active regions with different configurations.

19. The device of claim 18,
wherein in the memory cells, the active regions for p-type transistors and n-type transistors extend lengthwise along a first direction at different lengths,
wherein in the logic cells, the active regions for p-type transistors and n-type transistors extend lengthwise along the first direction at same lengths.

20. The device of claim 18, further comprising edge strap areas on edges of the memory macro, wherein the edge strap areas span between the memory macro and the logic circuit areas, and the middle strap area spans a greater width than the edge strap areas along a same direction.
